(19) United States
(12) Patent Application Publication
(10) Pub. No.: US 2025/0372854 A1
(43) Pub. Date: Dec. 4, 2025

(54) CRYOSTAT WITH ELECTROMAGNETIC SHIELDING

(71) Applicant: INTERNATIONAL BUSINESS MACHINES CORPORATION, Armonk, NY (US)

(72) Inventors: Brian Paul Gaucher, Brookfield, CT (US); Michael S. Gordon, Croton on Hudson, NY (US); Kevin Wayne Brew, Niskayuna, NY (US); Matthew Beck, Danbury, CT (US)

(21) Appl. No.: 18/732,540

(22) Filed: Jun. 3, 2024

(51) Int. Cl. H01P 1/30; G06N 10/40; H01P 1/04; H01P 3/127; H05K 9/00

(52) U.S. Cl. CPC H01P 1/30; G06N 10/40; H01P 1/042; H01P 3/127; H05K 9/0056

(57) ABSTRACT

An enclosure is constructed of multiple sections joined end-to-end at joints. Each joint includes a waveguide flange at one end of one of the sections. The waveguide flange defines a waveguide channel that is configured proportionally to a predetermined electromagnetic frequency. Each joint also includes a shield flange at one end of another section joined to the waveguide flange. The shield flange defines a shield surface for the waveguide channel.

### BACKGROUND

### Technical Field

The present disclosure generally relates to processing microwave control signals for enhanced fidelity, and more particularly but not by way of limitation, to stabilizing amplitude and reducing noise and interference during implementation of microwave control signals.

### Description of the Related Art

Enhancing signal fidelity is useful in many contexts, such as to reduce errors from disturbances that can occur from electromagnetic interference and signal loss. Amplitude stability and noise mitigation can become more challenging where tighter error margins come into play in low latency, high sensitivity computer systems such as quantum computing systems.

Superconducting quantum computing is an implementation of a quantum computer with superconducting electronic circuits. Quantum computation studies the application of quantum phenomena for information processing and communication. Various models of quantum computation exist, and some popular models include the concepts of qubits and quantum gates. A qubit is a generalization of a bit that has two possible states but can be in a quantum superposition of both states. A quantum gate is a generalization of a classical logic gate, however the quantum gate describes the transformation that one or more qubits will experience after the gate is applied on them, given their initial state. Various quantum phenomena, such as superposition and entanglement, do not have analogs in the world of classical computing and therefore may involve special structures, techniques, temperature environments, and materials.

### SUMMARY

According to one embodiment, an enclosure is constructed of multiple sections joined end-to-end at joints. Each joint includes a waveguide flange at one end of one of the sections. The waveguide flange defines a waveguide channel that is configured proportionally to a predetermined electromagnetic frequency. Each joint also includes a shield flange at one end of another section joined to the waveguide flange. The shield flange defines a shield surface for the waveguide channel.

In an embodiment, the waveguide channel is equidistant from a center axis of the waveguide flange.

In an embodiment, the waveguide flange defines two or more waveguide channels, and the shield flange defines the shield surface for two or more of the waveguide channels.

In an embodiment, the waveguide flange has a first peripheral sheath that covers the joint. The shield flange has a second peripheral sheath interlocking the first peripheral sheath in a close mating engagement to define an attenuation channel between the first peripheral sheath and the second peripheral sheath.

In an embodiment, the first and second interlocking sheaths form outermost surfaces of the joint. In another embodiment the first and second interlocking sheaths form innermost surfaces of the joint.

In an embodiment, an elastomeric sealing member is sandwiched between the waveguide flange and the shield flange outboard of the waveguide channel.

In an embodiment, the enclosure is configured as a cryostat for a quantum computing system.

In an embodiment, the waveguide channel surrounds a sample enclosed within the cryostat.

According to one embodiment, an enclosure is constructed of multiple sections joined end-to-end at joints. Each joint has a first section having a waveguide flange with a first peripheral sheath that covers the joint and defines a waveguide channel. The joint also has a second section having a second peripheral sheath interlocking the first peripheral sheath in a close mating engagement to define a shield surface for the waveguide channel.

In an embodiment, the interlocking first and second peripheral sheaths define an attenuation channel.

In an embodiment, the first and second interlocking sheaths form outermost surfaces of the joint. In another embodiment, the first and second interlocking sheaths form innermost surfaces of the joint.

In an embodiment, the waveguide channel is equidistant from a center axis of the sections.

In an embodiment, the waveguide flange defines two or more waveguide channels, and the shield flange defines the shield surface for two or more of the waveguide channels.

In an embodiment, an elastomeric sealing member is sandwiched between the waveguide flange and the shield flange outboard of the waveguide channel.

In an embodiment, the enclosure is configured as a cryostat for a quantum computing system.

In an embodiment, the waveguide channel surrounds a sample enclosed within the cryostat.

According to one embodiment, a method is provided for attenuating electromagnetic signals with an enclosure constructed of multiple sections that are joined together end-to-end at joints surrounding a center axis. The method includes determining a target frequency. In a first section having a waveguide flange, a waveguide channel is formed at a radius from the center axis and with a depth that is proportional to the target frequency. In a second section having a shield flange, a shield surface is formed for the waveguide channel. The waveguide flange and the shield flange are joined together to form the joint.

In an embodiment, a length of the waveguide flange along the radius is selected and a depth of the waveguide channel is selected so that the length and depth sum to about a half-wavelength of the target frequency.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition to or instead of. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 diagrammatically depicts a quantum computing system, consistent with illustrative embodiments.

FIG. 2 depicts a cryostat enclosure constructed of multiple sections joined end-to-end at joints, consistent with illustrative embodiments.

FIG. 3 isometrically depicts a waveguide flange in one of the sections in FIG. 2, consistent with illustrative embodiments.

FIG. 4 is a cross-sectional depiction of a waveguide flange in one of the sections of FIG. 2 joined end-to-end with a shield flange in another one of the sections in FIG. 2.

FIG. 5 is similar to FIG. 4 and further depicts the waveguide flange and the shield flange having interlocking sheaths forming outermost surfaces of the joint.

FIG. 6 is similar to FIG. 5 and further depicts the waveguide flange and the shield flange having interlocking sheaths forming innermost surfaces of the joint.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well-known methods, procedures, and/or components have been described at a relatively high-level, without detail, to avoid unnecessarily obscuring aspects of the present teachings.

Although the terms first, second, third, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It is to be understood that other embodiments can be used, and structural or logical changes can be made without departing from the spirit and scope defined by the claims. The description of the embodiments is not limiting. In particular, elements of the embodiments described hereinafter may be combined with elements of different embodiments.

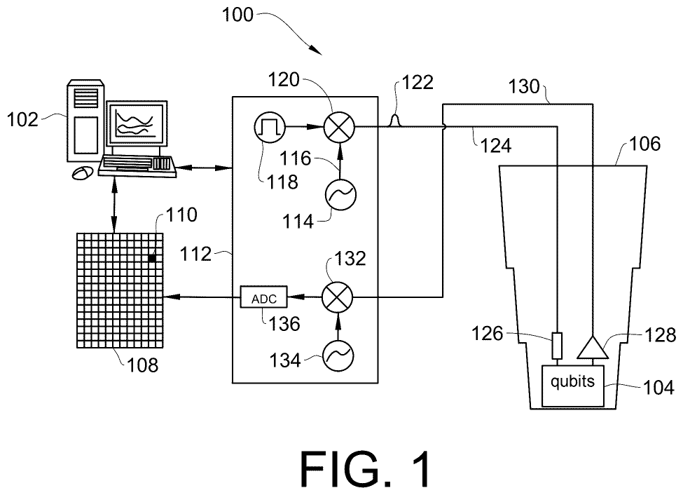

In this disclosure of illustrative embodiments, FIG. 1 depicts a quantum computing system 100. The quantum computing system 100 generally has a control computer 102 configured to perform classical computing processes to control, read, and write signals to qubits 104 included in a cryostat (or dilution refrigerator) 106. The control computer 102 typically operates at room temperature, which can be about 300 Kelvin (K). The cryostat 106 typically removes heat in stages, such as a first stage reducing the temperature to about 1 K, a second stage to about 100 milliKelvin (mK), and a third stage to less than about 25 mK. The control computer 102 includes or has access to a computer memory 108 that can be mapped to registers 110, which are individually programmable to store either a logical “1” or a logical “0” value. Multiple registers 110 can be grouped into register blocks for storing data values and data structures. These stored values can reflect the values written to and retrieved from the qubits 104. The control computer 102 also includes or has access to a microwave control and measurement hardware block 112. Within the measurement hardware block 112, an oscillator 114 can generate an analog signal 116 of a desired microwave frequency. The analog signal 116 can be combined with the output of a pulse generator 118 by a mixer 120, such as an in-phase and quadrature (I-Q) mixer. In this manner, the correct signal 122 to control the qubits 104 can be imparted to a drive line 124. A signal 122 of a selected microwave frequency transmitted on the drive line 124 typically passes through one or more attenuation blocks 126 to reduce signal noise.

In one example, to read out the qubit state, a microwave signal can be applied to the microwave readout cavity. The transmitted (or reflected) microwave signal goes through low-noise amplifiers 128. A read line 130 can feed the readout signal to another mixer 132 and phase-locked oscillator 134, then through an analog-to-digital converter (ADC) 136 to store the read values to the memory 108. Alternatively, or in addition, a microwave signal (e.g., pulse) can be transmitted on the drive line 124 to entangle the qubits 104.

The amplitude and/or phase of the microwave readout signal carries information about the qubit state. The power of the microwave signal carrying the quantum information about the qubit state is usually weak (e.g., on the order of a few microwave photons). Even very low levels of electromagnetic interference and/or signal loss can be detrimental to write signal and read signal fidelity.

To measure this weak microwave signal with room temperature electronics (i.e., outside the refrigerated environment), low-noise quantum-limited amplifiers (QLAs), such as Josephson amplifiers and travelling-wave parametric amplifiers (TWPAs), can be used as preamplifiers (i.e., first amplification stage) at the output of the quantum system to boost the quantum signal, while adding a low (e.g., the minimum) amount of noise as dictated by quantum mechanics, in order to improve the signal-to-noise ratio of the output.

It has been determined that to increase the reliability of a quantum computer, improvements can be made to reduce the error rates, which is relevant to manipulate qubit states accurately and perform sequential operations that provide consistent results and not merely unreliable data. Some such errors stem from electromagnetic interference originating outside the cryostat and input/output (I/O) signal leakage from inside the cryostat.

In one aspect, the teachings herein are based on Applicants' insight that the cryostat can be favorably constructed to include waveguides to attenuate electromagnetic energy and thereby shield a sample enclosed in the cryostat. Accordingly, embodiments of the present disclosure are further based on recognition that issues unique to quantum circuits have been taken into consideration when evaluating applicability of conventional electromagnetic shielding techniques, and, in particular, to selecting structures and methods used for interacting efficiently with qubits.

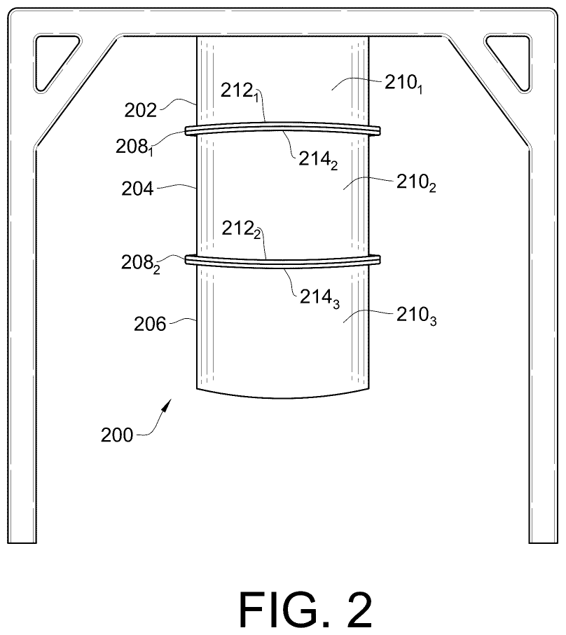

FIG. 2 depicts an enclosure 200 constructed of multiple sections 202, 204, 206 joined end to end at joints 208. The enclosure 200 can be configured for use in the cryostat 106 in FIG. 1, for example. In these illustrative embodiments, the top section 202 has a cylindrical central body 210₁ that terminates at a lower end with a waveguide flange 212₁. The middle section 204 has a cylindrical central body 210₂ that terminates at an upper end with a shield flange 214₂ and that terminates at a lower end with a waveguide flange 212₂. The bottom section 206 has a cylindrical body 210₃ that terminates at an upper end with a shield flange 214₃.

Each joint 208 is made of a waveguide flange 212 at one end of one of the sections 202, 204, 206 that is joined to a shield flange 214 of another section 202, 204, 206. A mating waveguide flange 212 and shield flange 214 can be permanently joined together such as by welding them, or they can be removably joined together such as with removable fasteners. As set forth in details that follow, each waveguide flange 212 defines a waveguide channel that is configured proportionally to a predetermined bandwidth of electromagnetic frequencies. Thus, the waveguide channel can be configured to attenuate a target frequency within the predetermined bandwidth. Also discussed in detail below, each shield flange 214 defines a shield surface for the waveguide channel in the mating waveguide flange 212.

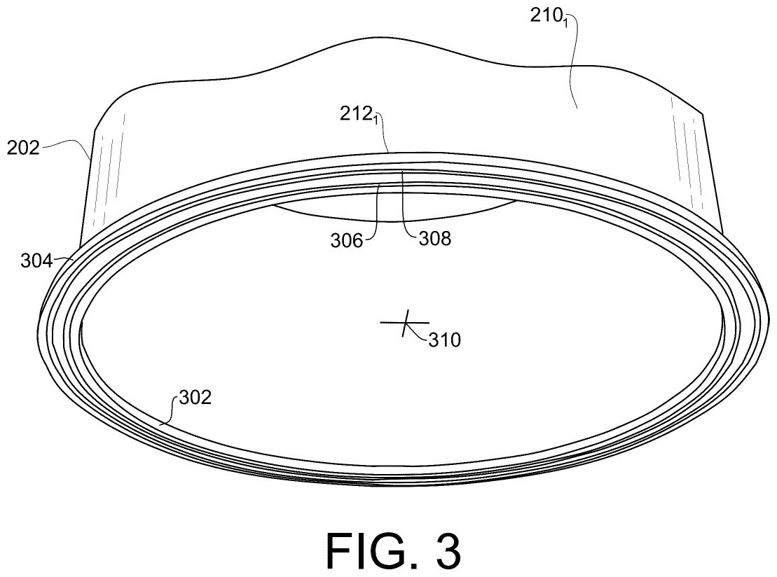

FIG. 3 is an isometric view of the lower end of the top section 202, depicting the mating surface of its waveguide flange 212₁. In these embodiments the waveguide flange 212₁ is circular, having an inner edge 302 and an outer edge 304. The waveguide flange 212₁ can also define one or more circular or semi-circular waveguide channels. In this example, two waveguide channels 306, 308 are formed in the waveguide flange 212₁ around a center axis 310. These waveguide channels 306, 308 surround a sample enclosed within the enclosure 200 (FIG. 2).

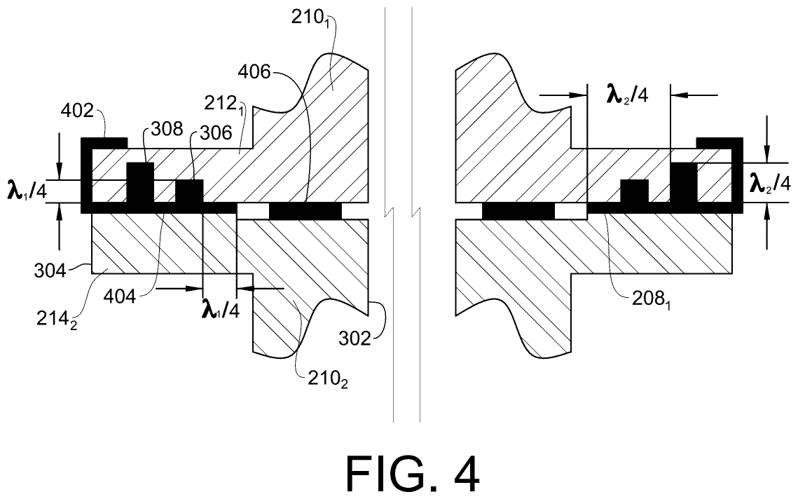

FIG. 4 is a cross-section view through a diameter of the joint 208₁ (FIG. 2), which is made by joining the waveguide flange 212₁ and the shield flange 214₂ together. An electrical lossy, vacuum gasket 402 is configured to fill the waveguide channels 306, 308 and to seal the dielectric gap between the bottom surface of the waveguide flange 212₁ and the top surface of the shield flange 214₂. In this example, the gasket 402 is also configured to wrap around the waveguide flange 212₁ outside the joint 208₁. The shield flange 214₂ defines a shield surface 404 for both waveguide channels 306, 308 in the waveguide flange 212₁. The shield surface 404 is closely spaced from and parallel to the waveguide flange 212₁ at the high-impedance opening of each waveguide channel 306, 308.

By configuring the waveguide channels 306, 308 proportionally to one or more target frequency bands, the mating waveguide flange 212₁ and shield flange 214₂ create a multi-band, multi-frequency waveguide filter. Radio frequency (RF) signals originating inside the enclosure 200 (FIG. 2) and that leak out through the normally RF porous joints 208₁, 208₂, or those originating outside the enclosure 200 and leaking in, can be detrimental disturbances to quantum computations. Such disturbances can be significantly attenuated by the addition of a specifically configured waveguide flange 212₁, shield flange 214₂, and optional gasket 402. By way of example, if a system required the management of two RF signals and spurious energies, one at 4 giga-Hertz (GHz) and one at 8 GHz, then the waveguide channels 306, 308 of FIGS. 3 and 4 can be configured as two quarter-wave waveguide notches. For example, channel 306 can be configured to attenuate the higher frequency 8 GHz spurious energy. Its distance from the innermost edge of the shield surface 404 can be configured as a one-quarter (¼) of the spurious energy's wavelength (or λ₁/4), and its depth can likewise be configured to be ¼ of the spurious energy's wavelength (or quarter wave). A quarter wave is defined by the following equation:

$$λ = \frac{c}{f √ e}$$

where:
   λ is the wavelength of the spurious energy;
   c is the speed of light;
   f is the frequency of the spurious energy; and
   √e is the square root of the dielectric constant of the gasket 402.

Thus, for a gasket material having a dielectric constant e equal to 1.0, the quarter wave distance λ₁/4 from the innermost edge of the shield surface 404 to the channel 306, as well as the quarter wave depth λ₁/4 of the channel 306, would be ˜9.4 mm. Likewise, the quarter wave distance λ₂/4 from the innermost edge of the shield surface 404 to the channel 308, as well as the quarter wave depth λ₂/4 of the channel 308, would be ˜18.8 mm. The rest of the gasket 402 beyond the channel 308 can provide continuity for vacuum vessel sealing as well as linear attenuation of any residual spurious signals that remain.

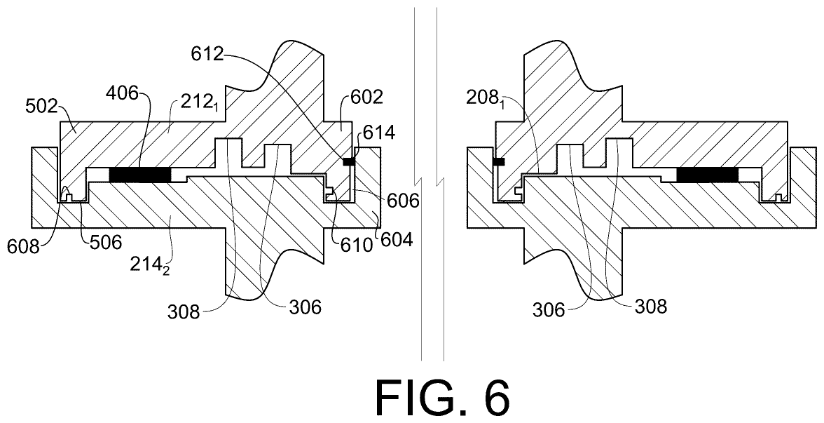

Note that in the embodiments of FIG. 4 the waveguide channels 306, 308 are positioned outboard of an elastomeric sealing member 406, such as an O-ring, sandwiched between the waveguide flange 212₁ and the shield flange 214₂ for retaining a vacuum state inside the enclosure 200 (FIG. 2). FIG. 6 below discloses alternative embodiments in which the waveguide channels 306, 308 can be positioned inboard of the elastomeric sealing member 226.

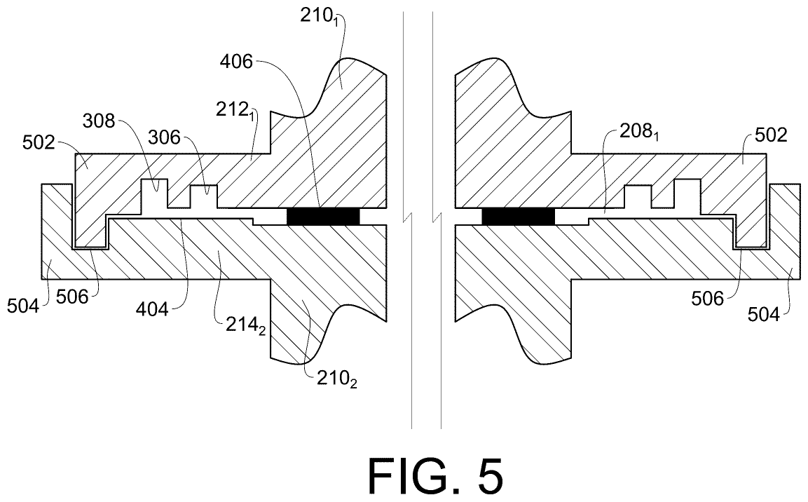

FIG. 5 is a cross-section view similar to FIG. 4 but without the gasket 402, and with the waveguide flange 212₁ further forming a first peripheral sheath 502 that covers the joint 208₁. The shield flange 214₂ further forms a second peripheral sheath 504 interlocking the first peripheral sheath 502 in a close mating engagement to define an attenuation channel 506 therebetween. The first and second interlocking sheaths 502, 504 form the outermost surfaces of the joint 208₁.

FIG. 6 is another cross-section view similar to FIG. 5 but with the waveguide flange 212₁ further forming an opposing peripheral sheath 602 that covers the joint 208₁. The shield flange 214₂ further forms an opposing second peripheral sheath 604 interlocking the first peripheral sheath 602 in a close mating engagement to define an opposing attenuation channel 606 therebetween. The opposing first and second interlocking sheaths 602, 604 form the innermost surfaces of the joint 208₁.

The embodiments of FIG. 6 also rearrange the sealing member (e.g., O-ring) 406 to be outboard of the waveguide channels 306, 308. FIG. 6 further depicts the first peripheral sheath 502 of the waveguide flange 212₁ can define another waveguide channel 608 in the attenuation channel 506. Likewise, the opposing peripheral sheath 602 of the waveguide flange 212₁ can define two waveguide channels 610, 612 in the attenuation channel 606. A gasket 614 is depicted in the waveguide channel 612 to provide both RF attenuation and vacuum sealing in the attenuating channel 606. The corners of the tortuous attenuation channels 506, 606 can be altered, such as radiused and chamfered and the like, to fine tune the respective RF attenuation notches in the attenuation channels 506, 606.

In these embodiments, the joints 208₁, 208₂ (FIG. 2) are tightened to compress elastomeric sealing members 402, 406 for sealing the vacuum state in the enclosure 200. The sealing members 402, 406 can be configured to include electrically conducting materials to attenuate electromagnetic signals passing through them. Additionally, spring or finger gaskets composed of beryllium copper and the like can be placed in the waveguide channels to enhance electrical contact (e.g., grounding) and thereby provide higher levels of signal attenuation.

These configurations further enable an inventive method of attenuating electromagnetic signals with an enclosure constructed of multiple sections that are joined together end-to-end at joints surrounding a center axis. The method includes determining a target frequency to attenuate. In a first section having a waveguide flange, the method includes forming a waveguide channel at a radius from a center axis and with a depth that are proportional to the target frequency. In a second section having a shield flange, the method further includes forming a shield surface for the waveguide channel. The method further includes joining the waveguide flange to the shield flange to form a joint.

The descriptions of the various embodiments of the present teachings have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings. The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain. Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed:

1. An enclosure constructed of multiple sections joined end-to-end at joints, each joint comprising:
a waveguide flange at one end of one of the sections and defining a waveguide channel configured proportionally to a predetermined electromagnetic frequency; and
a shield flange at one end of another section joined to the waveguide flange and defining a shield surface for the waveguide channel.

2. The enclosure of claim 1, wherein the waveguide channel is equidistant from a center axis of the waveguide flange.

3. The enclosure of claim 1, wherein:
the waveguide flange defines two or more waveguide channels; and
the shield flange defines the shield surface for two or more of the waveguide channels.

4. The enclosure of claim 1, wherein:
the waveguide flange has a first peripheral sheath that covers the joint; and
the shield flange has a second peripheral sheath interlocking the first peripheral sheath in a close mating engagement to define an attenuation channel between the first peripheral sheath and the second peripheral sheath.

5. The enclosure of claim 1, wherein first and second interlocking sheaths form outermost surfaces the joint.

6. The enclosure of claim 1, wherein first and second interlocking sheaths form innermost surfaces of the joint.

7. The enclosure of claim 1, further comprising an elastomeric sealing member sandwiched between the waveguide flange and the shield flange outboard of the waveguide channel.

8. The enclosure of claim 1, wherein the enclosure is a cryostat for a quantum computing system.

9. The enclosure of claim 8, wherein the waveguide channel surrounds a sample enclosed within the cryostat.

10. An enclosure constructed of multiple sections joined end-to-end at joints, each joint comprising:
a first section having a waveguide flange with a first peripheral sheath that covers the joint and defines a waveguide channel; and
a second section having a second peripheral sheath interlocking the first peripheral sheath in a close mating engagement to define a shield surface for the waveguide channel.

11. The enclosure of claim 10, wherein the interlocking first and second peripheral sheaths define an attenuation channel.

12. The enclosure of claim 10, wherein the first and second interlocking sheaths form outermost surfaces of the joint.

13. The enclosure of claim 10, wherein the first and second interlocking sheaths form innermost surfaces of the joint.

14. The enclosure of claim 10, wherein the waveguide channel is equidistant from a center axis of the sections.

15. The enclosure of claim 10, wherein:
the waveguide flange defines two or more waveguide channels; and
a shield flange defines the shield surface for two or more of the waveguide channels.

16. The enclosure of claim 10, further comprising an elastomeric sealing member sandwiched between the waveguide flange and a shield flange outboard of the waveguide channel.

17. The enclosure of claim 10, wherein the enclosure is a cryostat configured for a quantum computing system.

18. The enclosure of claim 17, wherein the waveguide channel surrounds a sample enclosed within the cryostat.

19. A method of attenuating electromagnetic signals with an enclosure constructed of multiple sections that are joined together end-to-end at joints surrounding a center axis, the method comprising:
determining a target frequency;
in a first section having a waveguide flange, forming a waveguide channel at a radius from the center axis and with a depth that are proportional to the target frequency; and
in a second section having a shield flange, forming a shield surface for the waveguide channel; and
joining the waveguide flange and the shield flange together to form a joint.

20. The method of claim 19, further comprising selecting a length of the waveguide flange along the radius and a depth of the waveguide channel to sum to about a half-wavelength of the target frequency.
